(19) United States
(12) Patent Application Publication
(10) Pub. No.: US 2008/0230797 A1
(43) Pub. Date: Sep. 25, 2008

(54) LED module and manufacturing method thereof

(76) Inventors: Hui-Hung Chang, Hsinchu City (TW); Sheng-Che Chien, Sinjhih City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/723,563

(22) Filed: Mar. 21, 2007

(51) Int. Cl. H01L 33/00

(52) U.S. Cl. 257/99; 438/26; 257/E33.058

(57) ABSTRACT

An LED module and a manufacturing method thereof are disclosed. The LED module includes a PCB and an LED chip connected with the PCB and a light congregating cup mounted on the PCB. Two ends of the light congregating cup define two hatches, the two hatches run-through each other and form a chip containing space within the light congregating cup. The LED chip is contained in the chip containing space and packaged therein by a packaging colloid. Because the light congregating cup is assembled with the PCB, the operating time of the production machine can be lowered. The defect rate, caused by traditional methods of setting the LED chip in a slantwise concave, can also be reduced. Moreover, the invention also provides a manufacturing method for the LED module.

### BACKGROUND OF THE INVENTION

1. Field of the Invention

The present invention relates to an LED module and a manufacturing method thereof, and more specifically to an LED module having a light congregating cup mounted on a printer circuit board, hence, the defect rate is reduced, and processing time is shortened.

2. Description of the Prior Art

Nowadays, LEDs (Light Emitting Diodes) are used widely due to their small volume, excellent shock-resistance, low power use and long lifespan. LEDs are used more and more widely in many fields so an important task is to use efficiently and congregate effectively the light source of the LED, and thereby avoid waste.

Please refer to FIG. 1 in which an LED structure of a prior art is shown. The LED includes a first support bracket 70 and a second support bracket 71 set in a photic colloid case, a groove 701 is defined on a top end of the first support bracket 70, an LED chip 72 is mounted inside the groove 701 to connect electrically with the first support bracket 70, the LED chip 72 is connected electrically with the second support bracket 71 via a conducting wire 73, light emitted from the LED chip 72 can't be dispersed to both sides due to the blocking caused by the groove 701. Thus, the light is congregated.

The groove 701 of the LED is set on the top end of the first support bracket 70 to congregate light, however, in processing, the concave depths of each groove 701 aren't accordant. This leads to repeated adjustment of the table when the conducting wire 73 is connected with the LED chip 72 and the first support bracket 70 (the process is called wire bonding). Moreover, the bottom of the groove 701 is sometimes processed slantwise (not shown) when molding, which leads to position deflection when the LED chip 72 is set into the groove 701.

For the LED structure, it is inevitable that the table be repeatedly adjusted when processing, which is inconvenient.

Hence, the inventors of the present invention believe that the shortcomings described above are able to be improved upon and suggest the present invention which is of a reasonable design and is an effective improvement based on deep research and thought.

### SUMMARY OF THE INVENTION

An object of the present invention is to provide an LED module and a manufacturing method thereof, which can omit the support brackets of the conventional LED module and the process of tin welding, the repeated adjustment of the table can also be omitted when using the wire bonding method, and when molding a groove, the situation in which the bottom of the groove is processed slantwise is avoided, hence, product stabilization is increased, and processing time is shortened.

To achieve the above-mentioned objects, an LED module is disclosed. The LED module comprises a PCB and an LED chip mounted on the PCB and connected with a conducting wire, the conducting wire is connected with the PCB and the LED chip, thereby, the PCB and the LED chip are connected electronically. A light congregating cup is assembled on the PCB. A first hatch and a second hatch are defined at two end faces of the light congregating cup respectively, the first hatch and the second hatch run through each other. A chip containing space is defined in the light congregating cup, and the LED chip is contained in the chip containing space. A packaging colloid is set in the chip containing space and packages the LED chip and the conducting wire.

Another LED module is also disclosed, the module comprises a PCB, a plurality of LED chips mounted on the PCB respectively and connected with conducting wires, and the conducting wires are connected with the PCB respectively. A plurality of light congregating cups define a plurality of chip containing spaces therein and are assembled on the PCB respectively, the LED chips are contained in the chip containing spaces respectively, and a plurality of packaging colloids packaging the LED chips and the conducting wires within the chip containing spaces.

A manufacturing method of the LED module is also disclosed, the method comprises providing a PCB, mounting an LED chip on the layout position of the PCB, and connecting electronically the LED chip with the PCB, and mounting a light congregating cup on the PCB. The light congregating cup defines a chip containing space, the LED chip is contained in the chip containing space, and packaging the chip containing space with a packaging colloid.

The advantages of the present invention are that the light congregating cup of the present invention is mounted on the PCB directly, which omits the LED support brackets of the prior art. The LED chip is connected with the PCB electronically, which omits the process and the cost of welding the support bracket onto the PCB by tin solder. The first hatch and the second hatch of the chip containing space run through each other, and the light congregating cup is mounted on the PCB directly, hence, product stabilization is increased, and processing time is shortened.

To further understand the features and technical contents of the present invention, please refer to the following detailed description and drawings related to the present invention. However, the drawings are only to be used as references and explanations, and not to limit the present invention.

### BRIEF DESCRIPTION OF THE DRAWINGS

FIG. 1 is a cutaway view of an LED structure of a prior art;

FIG. 2 is a cutaway view of an LED module of a first embodiment of the present invention;

FIG. 3 is a first isometric view of a conducting wire and an adhesive layer of the present invention;

FIG. 4 is a second isometric view of a conducting wire and an adhesive layer of the present invention;

FIG. 5 is a first isometric view of a light congregating cup of the present invention;

FIG. 6 is a second isometric view of a light congregating cup of the present invention;

FIG. 7 is a third isometric view of a light congregating cup of the present invention;

FIG. 8 is a forth isometric view of a light congregating cup of the present invention;

FIG. 9 is a light congregating effect view of an LED chip, a light congregating cup, and a light congregating unit of the present invention;

FIG. 10 is an isometric view of an LED module of a second embodiment of the present invention;

FIG. 11 is a flow chart of processing the LED module of the present invention.

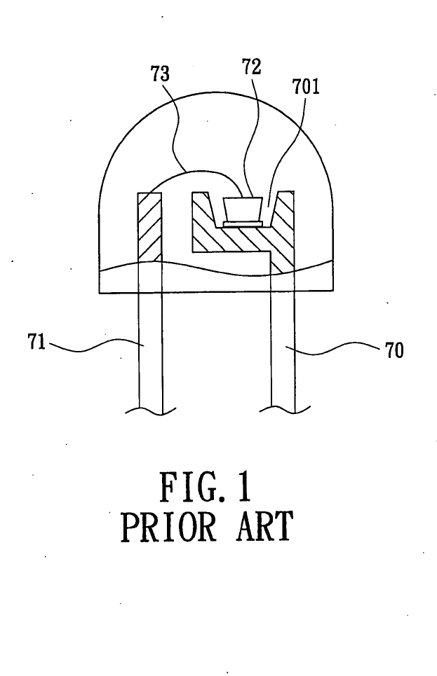

### DETAILED DESCRIPTION OF THE INVENTION

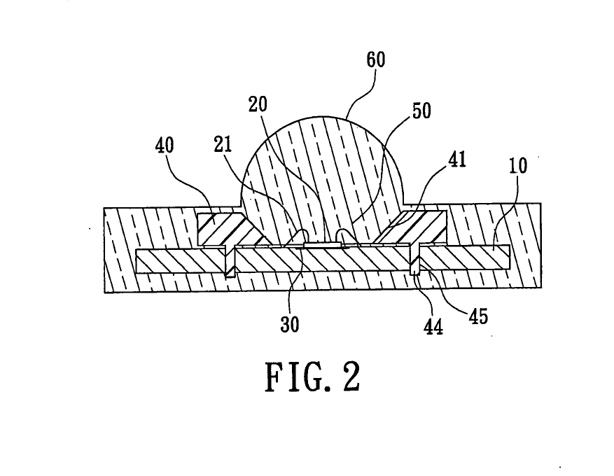

Please refer to FIG. 2, an LED module of the present invention is shown. The LED module includes a PCB (Printed Circuit Board) 10, an LED chip 20, an adhesive layer 30, a light congregating cup 40, a packaging colloid 50, and a light congregating unit 60.

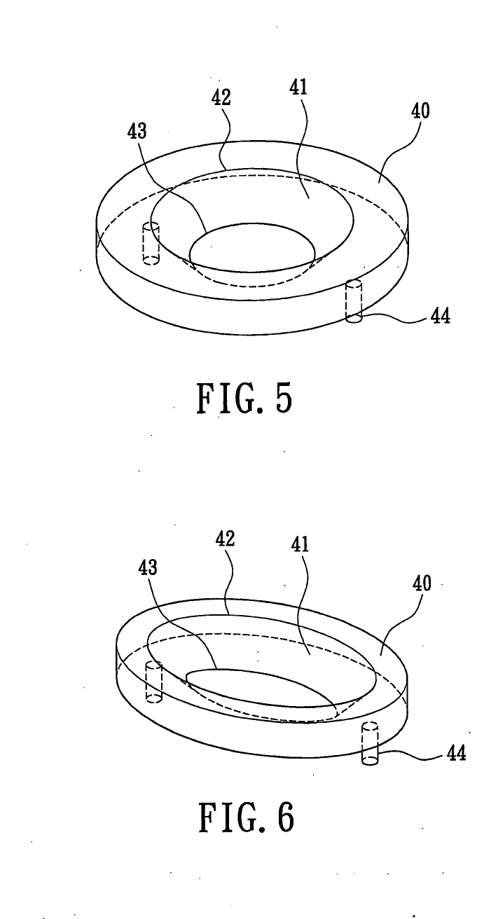

Please refer to FIGS. 2-5 in which an LED module of a first embodiment of the present invention is shown. The PCB 10 is made of glass fiber, metal or other hard materials. The exterior of the PCB 10 is covered by a wiring circuit layer (not shown).

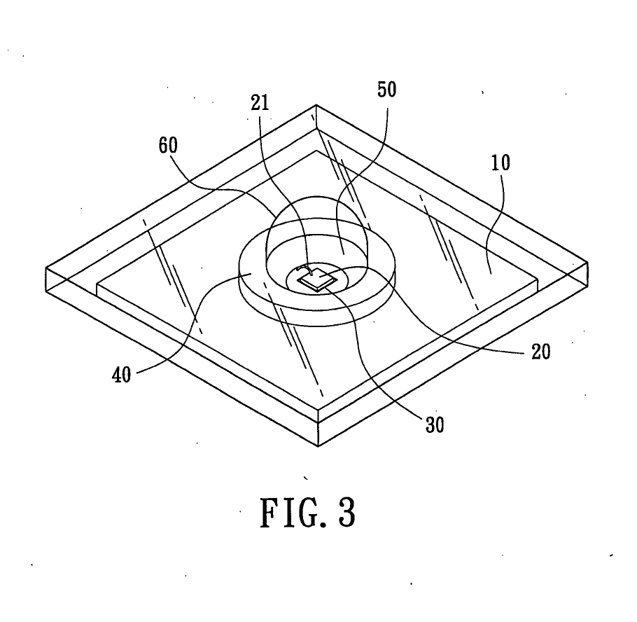

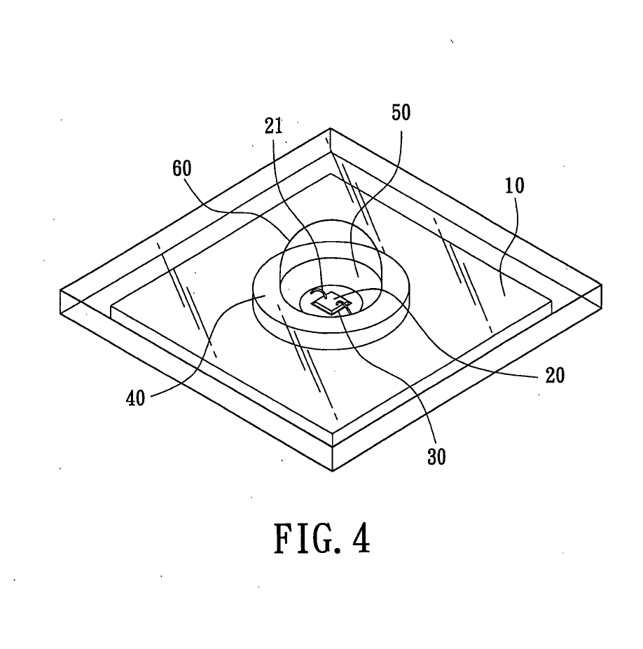

The LED chip 20 is mounted on the PCB 10 and connected with a conducting wire 21 (FIG. 3) or two conducting wires (FIG. 4). An other end of the conducting wire 21 is connected with the PCB 10. Two ends of the conducting wire 21 are welded onto the PCB 10 and the LED chip 20 respectively by an ultrasonic welding machine, hence, the LED chip 20 is connected electronically with the layout contact points set on the PCB 10.

The adhesive layer 30 is made of silver colloid or insulating colloid which is good at dispersing heat and is set between the printer circuit board 10 and the configuration side of the LED chip 20. The LED chip 20 is fixed onto the PCB 10 via the adhesive layer 30. The silver colloid is conductive and connects electronically with the LED chip 20 and the PCB 10.

The light congregating cup 40 is cup-shaped and is assembled on the PCB 10, a chip containing space 41 is defined in the light congregating cup 40 from the centre to inside thereof. The LED chip 20, the conducting wire 21 and the adhesive layer 30 are contained in the chip containing space 41. The chip containing space 41 forms a first hatch 42 and a second hatch 43 at the top edge and the bottom edge of the light congregating cup 40 respectively. The first hatch 42 and the second hatch 43 are circular, and the diameter of the first hatch 42 is bigger than that of the second hatch 43. Thus, a taper is formed on the inside wall of the chip containing space 41.

A plurality of protruding pieces 44 are set on the bottom side of the light congregating cup 40, a plurality of concave holes 45 are defined on the PCB 10 correspondingly, and the protruding pieces 44 and concave holes 45 engage reciprocally to assemble and fix the light congregating cup 40 onto the PCB 10.

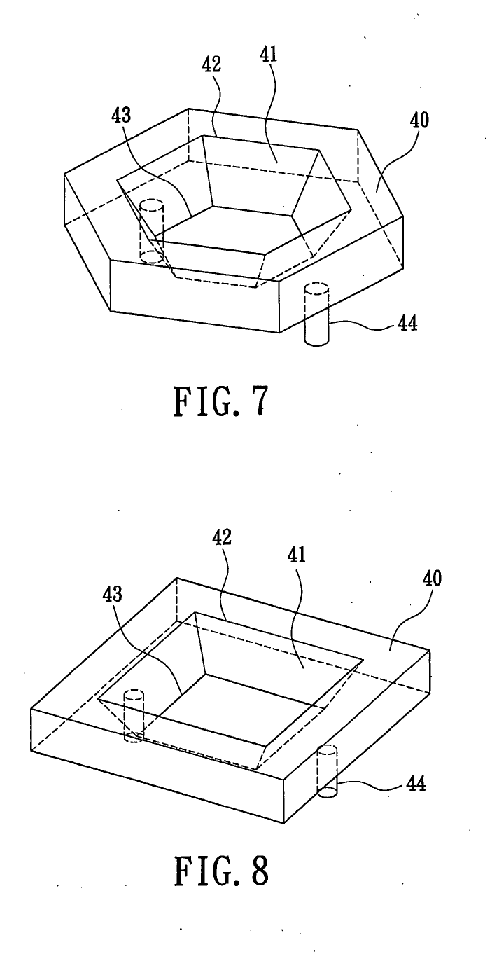

The light congregating cup 40 of the present invention is assembled and fixed onto the PCB 10 by engaging the protruding pieces 44 and concave holes 45. Selectively, the light congregating cup 40 can be adhered directly onto the PCB 10. Furthermore, the light congregating cup 40 can be made of ceramic, bakelite or plastic (not shown) according to different operation temperature or demands. According to different demands, the first hatch 42 and the second hatch 43 can be changed into an elliptic shape (FIG. 6), a polygonal shape (FIG. 7) or a quadrate shape (FIG. 8), etc.

The packaging colloid 50 is made of photic epoxy resins or silicone. The packaging colloid 50 packages the LED chip 20, the conducting wire 21 and the adhesive layer 30 within the chip containing space 41.

The light congregating unit 60 is set above the packaging plastic 50 and is convex and at least part of the first hatch 42 of the light congregating cup 40 is packaged therein. The light congregating unit 60 is made of optical PC (Polycarbonate) with high photic degree and injection-molded by a mould, to be then mounted outside the PCB 10 (not shown). Furthermore, the light congregating unit 60 can be made of epoxy resins with high photic degree and is in-molded by direct filling and jetting in a mould, and then mounted outside the PCB 10.

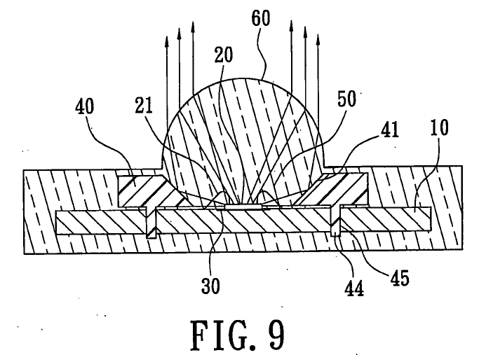

Please refer to FIG. 9. The light emitted from the LED chip 20 is congregated by the cone-shaped inside wall of the light congregating cup 40 and is then emitted farther beyond by the light congregating unit 60. Hence, the light is congregated and cannot dissipate.

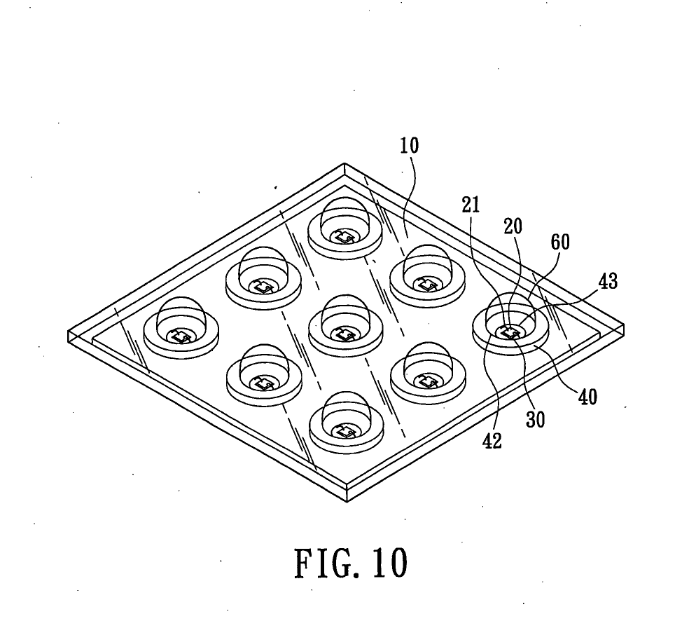

Please refer to FIG. 10 in which an LED module structure of a second embodiment of the present invention is shown. Differing from the first embodiment, the LED chip 20, the adhesive layer 30, the light congregating cup 40 and the packaging colloid 50 of the second embodiment are all configured with multitude and mounted on the PCB 10 respectively. The LED chips 20, the adhesive layers 30, the light congregating cups 40 and the packaging colloid 50 are mounted on the layout positions of the PCB 10 and connected electronically with the PCB 10 or assembled thereon in order; the LED chips 20 are contained within the chip containing spaces 41 respectively. However, except when mounting the light congregating units 60 onto the PCB 10 as in the first embodiment, a mould is used in the second embodiment. The mould corresponds to the layout positions of the PCB 10 directly for injecting and molding with epoxy resins or other similar materials, and the light congregating cups 40 set on the PCB 10 are packaged therein directly.

The PCB 10 of the second embodiment is a square panel and a length the square panel's sides are between 550 mm and 650 mm. As such, the LED module of the present invention can be used in a general illumination lamp. The size of the PCB 10 can be changed to set the LED module of the present invention in other devices such as traffic lights, road signs, and so on.

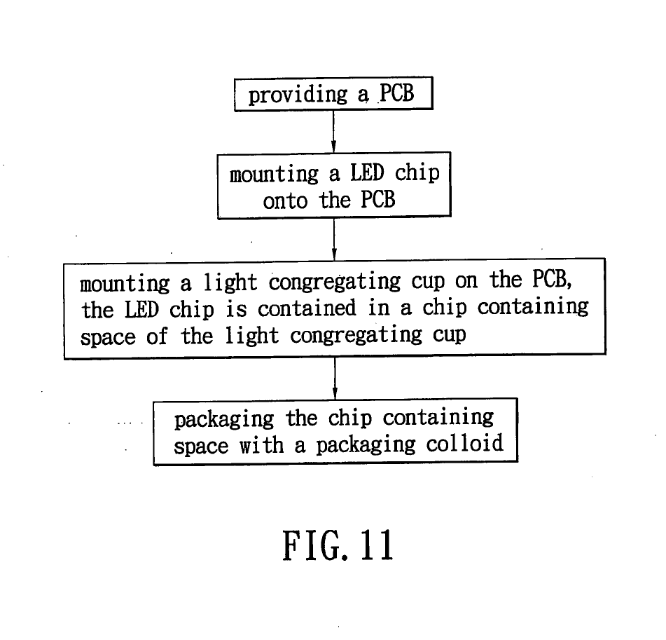

Please refer to FIG. 11, the manufacturing process of the LED module includes (referring to FIG. 2 at the same time):

(a) providing a PCB 10;

(b) mounting an LED chip 20 on the layout position of the PCB 10, and connecting electronically the LED chip 20 with the PCB 10;

(c) mounting a light congregating cup 40 on the PCB 10, a chip containing space 41 of the light congregating cup 40 contains the LED chip 20; and

(d) packaging the chip containing space 41 with a packaging colloid 50.

In summary, the characteristics and the functions of the present invention are:

1. the light congregating cup 40 of the present invention is mounted on the PCB 10, the first hatch 42, and the second hatch 43 of the chip containing spaces 41 that run through each other. The LED chip 20 is mounted on the PCB 10 directly so the defect rate of the LED modules re reduced, processing time is shortened, and brightness is enhanced.

2. the LED chip 20 is mounted on the PCB 10 directly, omitting the LED support bracket of the prior art. The LED chip 20 and the conducting wire 21 are welded onto the PCB 10 respectively by an ultrasonic welding machine to be connected electronically therewith, omitting the process and the cost of welding the support bracket onto the PCB by tin solder.

3. according to different demands and operation temperatures, the size and the material of the PCB 10 can be changed. The shapes and the materials of the first hatch 42 and the second hatch 43 can also be changed. Furthermore, a plurality of LED chips can be set and arranged according to demands. Next, a plurality of light congregating units are injected by in-molding to package the LED chips therein, hence, the LED module are waterproof.

What is disclosed above are only the preferred embodiments of the present invention, and therefore it is intended that the present invention not be limited to the particular embodiment disclosed. It should be understood by those skilled in the art that various equivalent changes may be made depending on the specification and the drawings of present invention without departing from the scope of the present invention.

What is claimed is:

1. AN LED (Light emitting diode) module, comprising:
a PCB (printed circuit board);
an LED chip mounted on the PCB and connected with a conducting wire, the conducting wire is connected with the PCB and the LED chip and thereby the PCB is connected electronically with the LED chip;
a light congregating cup assembled on the PCB, a first hatch and a second hatch are defined at two end faces of the light congregating cup respectively, the first hatch and the second hatch run through each other, a chip containing space is defined in the light congregating cup, and the LED chip is contained in the chip containing space; and
a packaging colloid set in the chip containing space to package the LED chip and the conducting wire.

2. The LED module as claimed in claim 1, wherein a light congregating unit is set above the packaging plastic to package at least part of the first hatch of the light congregating cup.

3. The LED module as claimed in claim 2, wherein the light congregating unit is mounted onto the PCB, or the material of the light congregating unit is the same to that of the packaging colloid and in-molded with the packaging colloid.

4. The LED module as claimed in claim 1, wherein the LED chip is fixed onto the PCB by an adhesive layer.

5. The LED module as claimed in claim 1, wherein the inside wall of the chip containing space of the light congregating cup defines a taper thereon.

6. The LED module as claimed in claim 1, wherein a plurality of protruding pieces are set on the bottom side of the light congregating cup, a plurality of concave holes are defined on the PCB correspondingly, the protruding pieces and concave holes are engaged reciprocally to fix the light congregating cup onto the PCB.

7. The LED module as claimed in claim 1, wherein the light congregating cup is adhered onto the PCB.

8. The LED module as claimed in claim 1, wherein the light congregating cup is made of ceramic, bakelite, or plastic.

9. The LED module as claimed in claim 1, wherein the first hatch and the second hatch have a circular shape, an elliptic shape, a quadrate shape or a polygonal shape.

10. AN LED module, comprising:
a PCB;
a plurality of LED chips mounted on the PCB respectively and connected with conducting wires, the conducting wires are connected with the PCB respectively;
a plurality of light congregating cups defining a plurality of chip containing spaces therein and assembled on the PCB respectively, the LED chips are contained in the chip containing spaces respectively; and
a plurality of packaging colloids packaging the LED chips set in the chip containing space and packaging the LED chips and the conducting wires within the chip containing spaces.

11. The LED module as claimed in claim 10, wherein the PCB is a square panel, and a length of the square panel's side is between 550 mm and 650 mm.

12. A manufacturing method of an LED module, comprising:
providing a PCB;
mounting an LED chip on the layout position of the PCB, and connecting electronically the LED chip with the PCB;
mounting a light congregating cup on the PCB, the light congregating cup defining a chip containing space, the LED chip is contained in the chip containing space; and
packaging the chip containing space with a packaging colloid.

13. The manufacturing method of the LED module as claimed in claim 12, wherein the LED chip is fixed onto the PCB by an adhesive layer.

14. The manufacturing method of the LED module as claimed in claim 12, wherein the LED chip is connected with a conducting wire, and two ends of the conducting wire are connected with the PCB and the LED chip respectively and thereby the PCB and the LED chip are connected electronically.

15. The manufacturing method of the LED module as claimed in claim 14, wherein the two ends of the conducting wire are welded by an ultrasonic welding machine to make the conducting wire connect electronically with the PCB and the LED chip respectively.

16. The manufacturing method of the LED module as claimed in claim 12, wherein a plurality of protruding pieces are set on the bottom side of the light congregating cup, a plurality of concave holes are defined on the PCB correspondingly, the protruding pieces and concave holes are engaged reciprocally to fix the fight congregating cup onto the PCB.

17. The manufacturing method of the LED module as claimed in claim 12, wherein the light congregating cup is adhered onto the PCB.

18. The manufacturing method of the LED module as claimed in claim 12, wherein a first hatch and a second hatch are defined on two end faces of the light congregating cup respectively, at least of part of the first hatch of the light congregating cup packages a light congregating unit.

19. The manufacturing method of the LED module as claimed in claim 18, wherein the light congregating unit is mounted onto the PCB or is in-molded with the packaging colloid.
